(19) United States
(12) Patent Application Publication
(10) Pub. No.: US 2026/0247581 A1
(43) Pub. Date: Aug. 20, 2026

(54) REFRIGERANT CIRCULATION SYSTEM

(71) Applicant: NIDEC CORPORATION, Kyoto (JP)

(72) Inventor: Toshihiko TOKESHI, Kyoto (JP)

(21) Appl. No.: 19/533,872

(22) Filed: Feb. 9, 2026

(30) Foreign Application Priority Data
Feb. 14, 2025 (JP) 2025-022404

(51) Int. Cl. H05K 7/20

(52) U.S. Cl. CPC H05K 7/20781; H05K 7/20281

(57) ABSTRACT

A refrigerant circulation system includes first heat exchange assemblies, a second heat exchange assembly, a first flow path, and a second flow path. A respective one of the first heat exchange assemblies is provided for each of objects to be cooled. The second heat exchange assembly includes a heat exchanger. The first flow path distributes a refrigerant from the second heat exchange assembly to the first heat exchange assemblies. The second flow path merges the refrigerant returned from the first heat exchange assemblies and allows the refrigerant to be collected by the second heat exchange assembly. Each of the first heat exchange assemblies includes a pump that passes the refrigerant supplied from the first flow path through a cooling assembly that cools a respective one of the objects to be cooled with the refrigerant, and sends the refrigerant to the second flow path.

### CROSS-REFERENCE TO RELATED APPLICATIONS

The present application claims priority under 35 U.S.C. § 119 to Japanese Patent Application No. 2025-022404, filed on Feb. 14, 2025, the entire contents of which are hereby incorporated herein by reference.

### 1. FIELD OF THE INVENTION

Example embodiments of the present disclosure relate to refrigerant circulation systems.

### 2. BACKGROUND

There is a refrigerant circulation system that supplies a refrigerant from one refrigerant circulation device to a plurality of racks that store objects to be cooled, thereby cooling the objects to be cooled.

However, in known refrigerant circulation systems, it is difficult to individually supply a refrigerant at appropriate flow rates to a plurality of objects to be cooled.

### SUMMARY

A refrigerant circulation system according to an example embodiment of the present disclosure includes first heat exchange assemblies, a second heat exchange assembly, a first flow path, and a second flow path. A respective one of the first heat exchange assemblies is provided for each of objects to be cooled. The second heat exchange assembly includes a heat exchanger. The first flow path distributes a refrigerant from the second heat exchange assembly to the first heat exchange assemblies. The second flow path merges the refrigerant returned from the first heat exchange assemblies and allows the refrigerant to be collected by the second heat exchange assembly. Each of the first heat exchange assemblies includes a pump. The pump passes the refrigerant supplied from the first flow path through a cooling assembly that cools the object to be cooled with the refrigerant, and sends the refrigerant to the second flow path.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an explanatory diagram illustrating a refrigerant circulation system according to an example embodiment of the present disclosure.

FIG. 2 is an explanatory diagram illustrating a refrigerant circulation system according to a first modified example of an example embodiment of the present disclosure.

FIG. 3 is an explanatory diagram illustrating a refrigerant circulation system according to a second modified example of an example embodiment of the present disclosure.

FIG. 4 is an explanatory diagram illustrating a refrigerant circulation system according to a third modified example of an example embodiment of the present disclosure.

FIG. 5 is an explanatory diagram illustrating a refrigerant circulation system according to a fourth modified example of an example embodiment of the present disclosure.

### DETAILED DESCRIPTION

Example embodiments of refrigerant circulation systems will be described in detail below with reference to the accompanying drawings. Note that the present disclosure is not limited to the example embodiments described below. In the following description, identical components will be denoted by the same reference numerals, and redundant descriptions will be omitted. The refrigerant circulation systems according to the example embodiments are systems that cool an object to be cooled by circulating a refrigerant.

One example of an object to be cooled is an electronic device that generates heat due to operation of a server device, a central processing unit (CPU), or the like stored in a server rack. One object to be cooled may be a single electronic device, or may include a plurality of electronic devices.

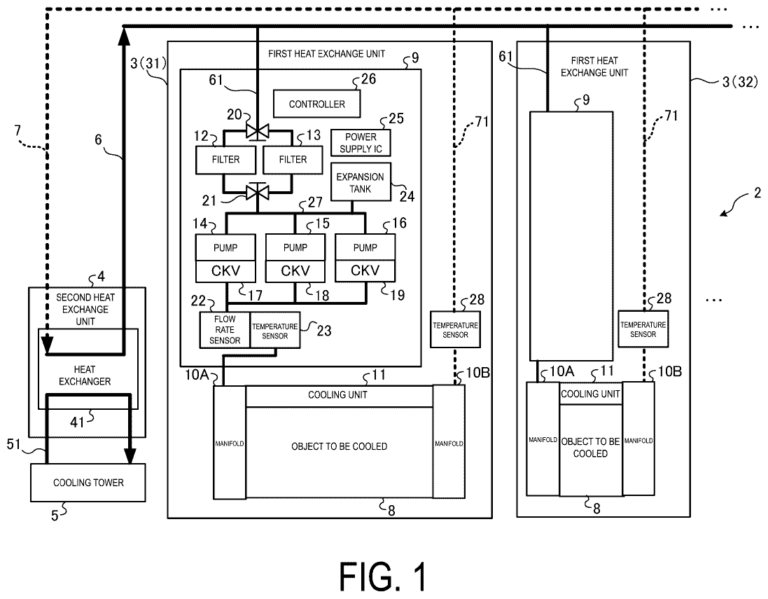

FIG. 1 is an explanatory diagram illustrating a refrigerant circulation system 2 according to an example embodiment. The refrigerant circulation system 2 includes a plurality of (here, two) first heat exchange assemblies 3 (31 and 32), a second heat exchange assembly 4, and a cooling tower 5. The first heat exchange assembly 3 is provided for an object 8 to be cooled.

In one example, the first heat exchange assembly 3 is provided in a separate rack in which the object 8 to be cooled is stored. The first heat exchange assemblies 31 and 32 have the same configuration. Thus, in FIG. 1, an internal configuration of a housing 9 (described below) provided in the first heat exchange assembly 32 is not illustrated.

The second heat exchange assembly 4 is provided separately from the first heat exchange assemblies 3. In one example, the second heat exchange assembly 4 is provided outside the rack in which the object 8 to be cooled is stored. The second heat exchange assembly 4 includes a heat exchanger 41. The first heat exchange assemblies 3 and the second heat exchange assembly 4 are connected by a first flow path 6 and a second flow path 7 through which a refrigerant flows.

The first flow path 6 is a refrigerant flow path that distributes the refrigerant from the second heat exchange assembly 4 to the first heat exchange assemblies 3. The second flow path 7 is a refrigerant flow path that merges the refrigerant returned from the first heat exchange assemblies 3 and allows the refrigerant to be collected by the second heat exchange assembly 4.

The second heat exchange assembly 4 and the cooling tower 5 are connected by a circulation path 51 for the refrigerant. The cooling tower 5 sends a primary refrigerant that is cooled inside the cooling tower 5 to the heat exchanger 41 of the second heat exchange assembly 4 through the circulation path 51, and cools the primary refrigerant returning from the heat exchanger 41 again and sends the cooled primary refrigerant to the heat exchanger 41.

The first heat exchange assembly 3 includes pumps 14 to 16 that pass a secondary refrigerant supplied from the first flow path 6 through a cooling assembly 11 and send the secondary refrigerant to the second flow path 7. Thus, the secondary refrigerant is sent from the first flow path 6 to the cooling assembly 11 by the pumps 14 to 16.

Thereafter, the secondary refrigerant cools the object 8 to be cooled by absorbing heat from the object 8 to be cooled as the secondary refrigerant passes through the cooling assembly 11, and is then sent to the second flow path 7 and returned to the heat exchanger 41 of the second heat exchange assembly 4. The secondary refrigerant is cooled by the cooled primary refrigerant circulating through the circulation path 51 as the secondary refrigerant passes through the heat exchanger 41, and is supplied again to each of the first heat exchange assemblies 3 through the first flow path 6. Note that, although a case where the secondary refrigerant is cooled by the primary refrigerant supplied from the cooling tower 5 to the heat exchanger 41 will be described here, this is merely an example. The secondary refrigerant according to the example embodiment may be cooled by another cooling device, such as a fan or a radiator.

In this way, the refrigerant circulation system 2 cools the object 8 to be cooled. Note that in FIG. 1, a flow path for the secondary refrigerant before absorbing heat from the object 8 to be cooled is indicated by a thick solid line, and a flow path for the secondary refrigerant after absorbing heat from the object 8 to be cooled is indicated by a thick dotted line. Note that in FIG. 1, the circulation path 51 for the primary refrigerant circulating between the cooling tower 5 and the second heat exchange assembly 4 is also indicated by a thick solid line.

As described above, in the refrigerant circulation system 2, each first heat exchange assembly 3 includes the pumps 14 to 16. Therefore, when heat generation amounts of objects 8 to be cooled differ, and thus the required cooling performance varies, the refrigerant circulation system 2 can provide the secondary refrigerant at an optimal flow rate to each object 8 to be cooled by adjusting the outputs of the pumps 14 to 16 for each first heat exchange assembly 3.

The configuration of the first heat exchange assembly 3 will be described in detail below. The first heat exchange assembly 3 includes the housing 9 that houses the pumps 14 to 16 and the like, manifolds 10A and 10B, the cooling assembly 11, a temperature sensor 28, and the like.

At least part of a forward path 61 for the secondary refrigerant, through which the secondary refrigerant is sent from the first flow path 6 to the cooling assembly 11, is located inside the housing 9. A return path 71 for the secondary refrigerant, through which the secondary refrigerant is sent from the cooling assembly 11 to the second flow path 7, is located outside the housing 9. Thus, the refrigerant circulation system 2 can simplify piping inside the housing 9 compared to a case where the forward path 61 and the return path 71 for the secondary refrigerant are located inside the housing 9.

Further, inside the housing 9 are located filters 12 and 13, the pumps 14 to 16, check valves (CKVs) 17 to 19, a first valve 20, a second valve 21, a flow rate sensor 22, a temperature sensor 23, an expansion tank 24, a power supply IC 25, a controller 26, and the like.

The filters 12 and 13 are connected in parallel between the first flow path 6 and the pumps 14 to 16. The first valve 20 is located between the first flow path 6 and the filters 12 and 13. The first valve 20 includes an inlet port for the secondary refrigerant connected to the first flow path 6, an outlet port for the secondary refrigerant connected to the filter 12, and an outlet port for the secondary refrigerant connected to the filter 13. The first valve 20 is a valve capable of switching a flow path for sending the secondary refrigerant supplied from the first flow path 6 to either the filter 12 or the filter 13.

The second valve 21 is located between the filters 12 and 13 and the pumps 14 to 16. The second valve 21 includes an inlet port for the secondary refrigerant connected to the filter 12, an inlet port for the secondary refrigerant connected to the filter 13, and an outlet port for the secondary refrigerant connected to the pumps 14 to 16. The second valve 21 is a valve capable of switching a flow path for sending the secondary refrigerant supplied from either the filter 12 or the filter 13 to the pumps 14 to 16.

In the refrigerant circulation system 2, the secondary refrigerant can be circulated with the secondary refrigerant passing through one of the filters 12 and 13, and not passing through the other. Thus, in the refrigerant circulation system 2, it is possible to replace the filter that does not pass the secondary refrigerant out of the filters 12 and 13 even during operation.

The pumps 14 to 16 are connected in parallel to the forward path 61. Thus, even when any of the pumps 14 to 16 fails, the refrigerant circulation system 2 can continue to operate using the other pumps that are not failed. The CKVs 17 to 19 are check valves connected to output sides of the pumps 14 to 16.

The expansion tank 24 is connected to a distribution flow path 27 that distributes the secondary refrigerant from the first flow path 6 to the pumps 14 to 16 that are connected in parallel. The expansion tank 24 is a tank that can adjust the internal pressure. When the internal pressure of the forward path 61 becomes equal to or higher than a predetermined value, the expansion tank 24 allows the secondary refrigerant to flow into the expansion tank 24 from the distribution flow path 27, adjusting the internal pressure of the forward path 61 to be less than the predetermined value. In the refrigerant circulation system 2, the expansion tank 24 is provided near the inlet ports, for the secondary refrigerant, of the pumps 14 to 16, which are prone to negative pressure, thereby further suppressing occurrence of cavitation inside the forward path 61.

The flow rate sensor 22 and the temperature sensor 23 are connected between the CKVs 17 to 19 in the forward path 61 and the manifold 10A. The flow rate sensor 22 detects a flow rate of the secondary refrigerant flowing through the forward path 61, and outputs a detection result to the controller 26. The temperature sensor 23 detects a temperature of the secondary refrigerant sent from the pumps 14 to 16 to the cooling assembly 11, and outputs a detection result to the controller 26.

The manifold 10A sends the secondary refrigerant supplied from the forward path 61 to the cooling assembly 11. In one example, the cooling assembly 11 is a cooling plate through which the secondary refrigerant flows. When the object 8 to be cooled includes a plurality of electronic devices, the cooling assembly 11 may be provided for each electronic device.

In this case, the manifold 10A distributes the secondary refrigerant to all of the cooling assemblies 11. Note that when an immersion cooling system is adopted, the cooling assembly 11 is a cooling tank in which the electronic device as the object 8 to be cooled is immersed in the secondary refrigerant.

The manifold 10B sends the secondary refrigerant that has passed through the cooling assembly 11 to the return path 71. When the object 8 to be cooled includes a plurality of electronic devices, the manifold 10B merges the secondary refrigerant flowing from the cooling assemblies 11 provided for the corresponding electronic devices and send the secondary refrigerant to the return path 71.

The temperature sensor 28 located outside the housing 9 is connected in the return path 71 between the manifold 10B and the second flow path 7. The temperature sensor 28 detects a temperature of the secondary refrigerant sent from the cooling assembly 11 to the second flow path 7, and outputs a detection result to the controller 26. As described above, the first heat exchange assembly 3 includes the temperature sensor 28 that detects the temperature of the secondary refrigerant after the secondary refrigerant passes through the cooling assembly 11. This allows the controller 26 to confirm whether cooling performance of the first heat exchange assembly 3 is sufficient, from the temperature of the secondary refrigerant detected by the temperature sensor 28.

The power supply IC 25 supplies power to the controller 26, the pumps 14 to 16, the flow rate sensor 22, and the temperature sensors 23 and 28. The power supply IC 25 also supplies power to the first valve 20 and the second valve 21 when the first valve 20 and the second valve 21 are solenoid valves.

The controller 26 includes a microcomputer including a central processing unit (CPU), a read only memory (ROM), a random access memory (RAM), and the like, and various circuits. The controller 26 comprehensively controls operation of the first heat exchange assembly 3 by executing, by the CPU, a program stored in the ROM using the RAM as a work area.

The controller 26 adjusts flow rates of the pumps 14 to 16 according to the temperature of the secondary refrigerant detected by the temperature sensor 28. In one example, when the temperature of the secondary refrigerant detected by the temperature sensor 28 becomes equal to or higher than a first threshold, the controller 26 increases the flow rates of the pumps 14 to 16 until the temperature of the secondary refrigerant becomes less than the first threshold. In addition, when the temperature of the secondary refrigerant becomes too low, the controller 26 can reduce the flow rates of the pumps 14 to 16 to suppress condensation. The first threshold can be freely set by the user.

Thus, for example, when an amount of heat generated by the object 8 to be cooled increases, the controller 26 of the first heat exchange assembly 31 can independently increase a flow rate of the secondary refrigerant in the first heat exchange assembly 31, thereby supplying an appropriate flow rate of the secondary refrigerant to the cooling assembly 11.

The controller 26 may be configured to adjust the flow rates of the pumps 14 to 16 according to the temperatures of the secondary refrigerant before and after passing through the cooling assembly 11. In this case, the controller 26 calculates a temperature difference by subtracting the temperature of the secondary refrigerant detected by the temperature sensor 23 provided on the forward path 61 from the temperature of the secondary refrigerant detected by the temperature sensor 28 provided on the return path 71.

Then, when the calculated temperature difference becomes equal to or greater than a second threshold, the controller 26 increases the flow rates of the pumps 14 to 16 until the temperature difference becomes less than the second threshold. Thus, even when the temperature of the secondary refrigerant flowing through the return path 71 rises, the controller 26 does not unnecessarily increase the flow rates of the pumps 14 to 16, thereby, suppressing an increase in power consumption of the pumps 14 to 16.

For example, in the first heat exchange assembly 31, the temperature of the secondary refrigerant flowing through the return path 71 may rise not due to the heat of the object 8 to be cooled for the first heat exchange assembly 31 but due to deterioration of heat exchange performance of the second heat exchange assembly 4 or due to the object 8 to be cooled for the other first heat exchange assembly 32.

In this case, the temperature of the secondary refrigerant flowing through the forward path 61 also rises, and even when the controller 26 increases the flow rates of the pumps 14 to 16 of the first heat exchange assembly 31, the controller 26 cannot lower the temperature of the secondary refrigerant flowing through the return path 71. Therefore, in such a case, the controller 26 can minimize the power consumption of the pumps 14 to 16 while providing optimal cooling performance by not unnecessarily increasing the flow rates of the pumps 14 to 16.

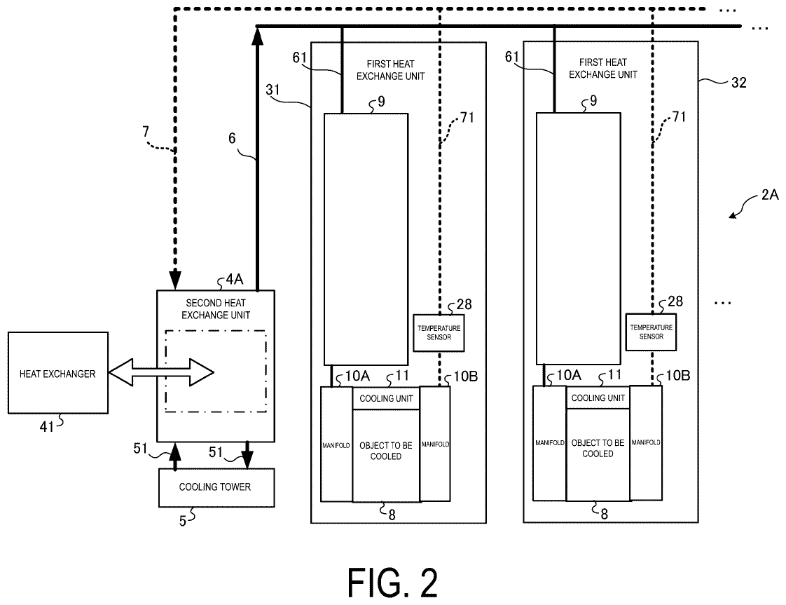

Next, a refrigerant circulation system 2A according to a first modified example of the example embodiment will be described with reference to FIG. 2. FIG. 2 is an explanatory diagram illustrating the refrigerant circulation system 2A according to the first modified example of the example embodiment.

As illustrated in FIG. 2, the refrigerant circulation system 2A according to the first modified example includes a second heat exchange assembly 4A with a configuration different from the second heat exchange assembly 4 illustrated in FIG. 1, but other configurations are similar to those of the refrigerant circulation system 2 illustrated in FIG. 1. Note that a configuration inside a housing 9 in first heat exchange assemblies 31 and 32 illustrated in FIG. 2 is similar to the configuration inside the housing 9 in the first heat exchange assembly 31 illustrated in FIG. 1.

A heat exchanger 41 of the second heat exchange assembly 4A is configured to be insertable into and removable from the second heat exchange assembly 4A. This makes it easy to adjust cooling performance of the refrigerant circulation system 2A by replacing the heat exchanger 41 with another one that has different heat exchange performance.

Further, since the heat exchanger 41 of the refrigerant circulation system 2A can be replaced with another one, maintenance can be easily performed by removing the heat exchanger 41. By attaching a different heat exchanger 41 to the second heat exchange assembly 4A and operating the different heat exchanger 41 during this time, maintenance of the heat exchanger 41 can be performed while the refrigerant circulation system 2A is operating.

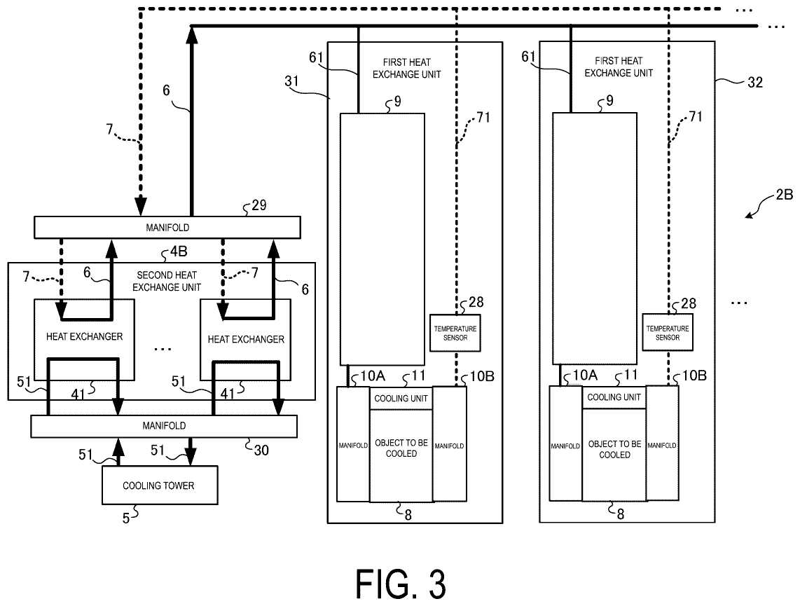

Next, a refrigerant circulation system 2B according to the second modified example of the example embodiment will be described with reference to FIG. 3. FIG. 3 is an explanatory diagram illustrating the refrigerant circulation system 2B according to the second modified example of the example embodiment.

As illustrated in FIG. 3, the refrigerant circulation system 2B according to the second modified example includes a second heat exchange assembly 4B with a configuration different from the second heat exchange assembly 4 illustrated in FIG. 1, but other configurations are similar to those of the refrigerant circulation system 2 illustrated in FIG. 1. Note that a configuration inside a housing 9 in first heat exchange assemblies 31 and 32 illustrated in FIG. 2 is similar to the configuration inside the housing 9 in the first heat exchange assembly 31 illustrated in FIG. 1.

The second heat exchange assembly 4B includes a plurality of heat exchangers 41. the plurality of heat exchangers 41 are connected in parallel to a first flow path 6 and a second flow path 7 via a manifold 29. Further, the plurality of heat exchangers 41 are connected in parallel to a cooling tower 5 via a manifold 30. In the example illustrated in FIG. 3, the second heat exchange assembly 4B includes two heat exchangers 41, but may include three or more heat exchangers 41. The manifold 29 has a function of distributing a secondary refrigerant flowing therein from the second flow path 7 to the plurality of heat exchangers 41, and a function of collecting the secondary refrigerant flowing therein from the plurality of heat exchangers 41 and discharging the collected secondary refrigerant into the first flow path 6. The manifold 30 has a function of collecting the secondary refrigerant flowing therein from the plurality of heat exchangers 41 and discharging the collected secondary refrigerant to the cooling tower 5, and a function of distributing the secondary refrigerant flowing therein from the cooling tower 5 to the plurality of heat exchangers 41.

Thus, even when some of the heat exchangers 41 in the second heat exchange assembly 4B fail, the secondary refrigerant can be cooled by the other heat exchanger 41, thereby improving redundancy of the heat exchangers 41. Further, the second heat exchange assembly 4B can easily adjust heat exchange performance by changing the number of the heat exchangers 41 that are operated simultaneously.

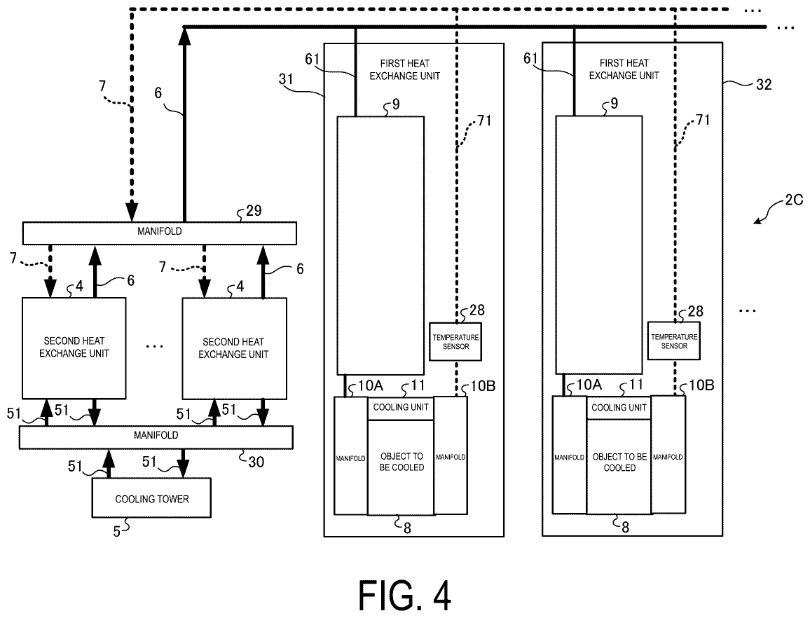

Next, a refrigerant circulation system 2C according to the third modified example of the example embodiment will be described with reference to FIG. 4. FIG. 4 is an explanatory diagram illustrating the refrigerant circulation system 2C according to the third modified example of the example embodiment.

As illustrated in FIG. 4, the refrigerant circulation system 2C according to the third modified example differs from the refrigerant circulation system 2 illustrated in FIG. 1 in that the refrigerant circulation system 2C includes a plurality of second heat exchange assemblies 4. Other configurations of the refrigerant circulation system 2C are similar to those of the refrigerant circulation system 2 illustrated in FIG. 1.

The plurality of second heat exchange assemblies 4 are connected in parallel to a first flow path 6 and a second flow path 7 via a manifold 29. Further, the plurality of second heat exchange assemblies 4 are connected in parallel to a cooling tower 5 via a manifold 30. In the example illustrated in FIG. 4, the refrigerant circulation system 2C includes two second heat exchange assemblies 4, but may include three or more second heat exchange assemblies 4.

Thus, even when one of the second heat exchange assemblies 4 in the refrigerant circulation system 2C fails, a secondary refrigerant can be cooled by the other second heat exchange assembly 4, thereby improving redundancy of the second heat exchange assemblies 4. Further, the refrigerant circulation system 2C can easily adjust heat exchange performance by changing the number of the second heat exchange assemblies 4 that are operated simultaneously.

Although the case where each first heat exchange assembly 3 includes the controller 26 has been described above, the controller 26 may be provided in only one of the first heat exchange assemblies 3. The controller 26 is communicably connected to each of the first heat exchange assemblies 3.

The controller 26 adjusts the flow rates of the pumps 14 to 16 of each first heat exchange assembly 3 according to the temperature of the secondary refrigerant after the secondary refrigerant passes through the cooling assembly 11, which is detected by the temperature sensor 28 provided on the return path 71 of each first heat exchange assembly 3.

Thus, in the refrigerant circulation systems 2, 2A, 2B, and 2C, the controller 26 is not required for the first heat exchange assembly 3 other than the one first heat exchange assembly 3 in which the controller 26 is provided. Therefore, the refrigerant circulation systems 2, 2A, 2B, and 2C can supply the secondary refrigerant at an appropriate flow rate to each of the plurality of objects 8 to be cooled individually, while suppressing an increase in cost.

Further, the controller 26 can provide optimum cooling performance to each of the objects 8 to be cooled by collectively controlling the first heat exchange assemblies 3 (31, 32, etc.). For example, since the flow rate that can flow through the first flow path 6 and the second flow path 7 is limited due to pressure loss, the controller 26 sends the secondary refrigerant to each of the first heat exchange assemblies 3 in order of priority, thereby efficiently cooling the objects 8 to be cooled.

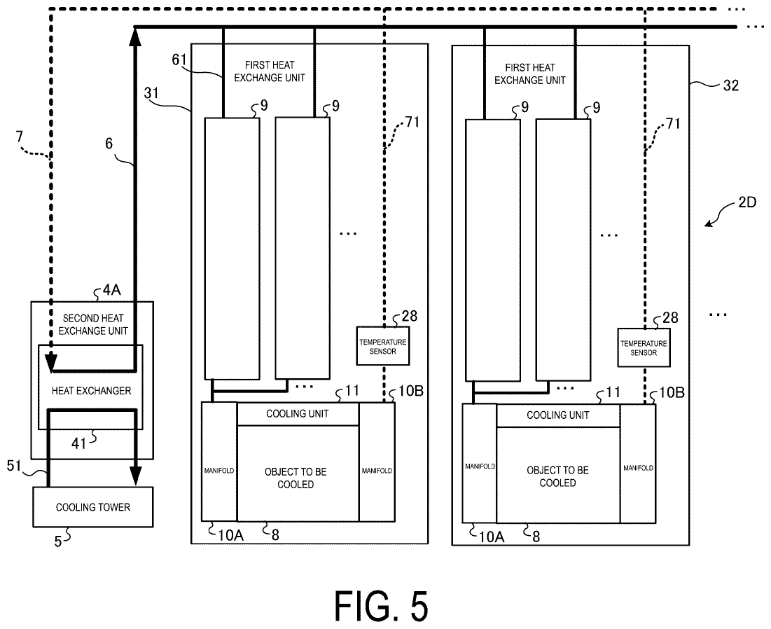

Next, a refrigerant circulation system 2D according to the fourth modified example of the example embodiment will be described with reference to FIG. 5. FIG. 5 is an explanatory diagram illustrating the refrigerant circulation system 2D according to the fourth modified example of the example embodiment.

As illustrated in FIG. 5, the refrigerant circulation system 2D according to the fourth modified example differs from the refrigerant circulation system 2 illustrated in FIG. 1 in that each of first heat exchange assemblies 3 (31 and 32) includes a plurality of housings 9. Other configurations of the refrigerant circulation system 2D are similar to those of the refrigerant circulation system 2 illustrated in FIG. 1.

An internal configuration of each of the housings 9 is similar to the internal configuration of the housing 9 illustrated in FIG. 1. A secondary refrigerant is supplied from a first flow path 6 to the housings 9. The secondary refrigerant is supplied from each of the housings 9 to a manifold 10A. Thus, even when, for example, a component inside one housing 9 fails, the refrigerant circulation system 2D can supply the secondary refrigerant from another housing 9 to the cooling assembly 11 via the manifold 10A, thereby improving redundancy.

The techniques according to the first to fourth modified examples can be combined as desired. For example, the refrigerant circulation system 2A according to the first modified example may include a plurality of second heat exchange assemblies 4A, which may be connected in parallel to the first flow path 6 and the second flow path 7.

The second heat exchange assembly 4A of the refrigerant circulation system 2A according to the first modified example may include a plurality of heat exchangers 41. In this case, the plurality of heat exchangers 41 may be connected in parallel to the first flow path 6 and the second flow path 7.

The heat exchanger 41 of the refrigerant circulation system 2B according to the second modified example may be insertable into and removable from the second heat exchange assembly 4B. The refrigerant circulation system 2B according to the second modified example may include a plurality of second heat exchange assemblies 4B. In this case, the plurality of second heat exchange assemblies 4B may be connected in parallel to the first flow path 6 and the second flow path 7.

The heat exchanger 41 included in each second heat exchange assembly 4 of the refrigerant circulation system 2C according to the third modified example may be configured to be insertable into and removable from the second heat exchange assembly 4. Each second heat exchange assembly 4 of the refrigerant circulation system 2C according to the third modified example may include a plurality of heat exchangers 41. In this case, the plurality of heat exchangers 41 may be connected in parallel to the first flow path 6 and the second flow path 7. The first heat exchange assembly 3 illustrated in FIGS. 1 to 4 may be replaced with the first heat exchange assembly including a plurality of housings 9 according to the fourth modified example.

The pumps 14 to 16 inside the housing 9 according to the example embodiments described above may be configured to be hot-swappable. This allows the refrigerant circulation systems 2, 2A, 2B, 2C, and 2D according to the example embodiments to operate continuously and improves maintainability. The housing 9 inside the first heat exchange assembly 3 may be configured to be hot-swappable. This improves maintainability of the components inside the housing 9 in the refrigerant circulation systems 2, 2A, 2B, 2C, and 2D according to the example embodiments.

The first flow path 6 and the second flow path 7 may be connected to the first heat exchange assembly 3 by couplings, and the first heat exchange assembly 3 may be configured to be able to be separated from the first flow path 6 and the second flow path 7. This facilitates the replacement of the first heat exchange assembly 3 in the refrigerant circulation systems 2, 2A, 2B, 2C, and 2D according to the example embodiments. Further, by using the coupling, even when any first heat exchange assembly 3 is removed, the secondary refrigerant can be sent to the other first heat exchange assembly through the first flow path 6 without a risk of leakage of the secondary refrigerant.

Note that the present technology can have configurations such as the following.
(1)

A refrigerant circulation system including first heat exchange assemblies, each of the first heat exchange assemblies being provided to each of objects to be cooled, a second heat exchange assembly including a heat exchanger, a first flow path that distributes a refrigerant from the second heat exchange assembly to the first heat exchange assemblies, a second flow path that merges the refrigerant returned from the first heat exchange assemblies and allows the refrigerant to be collected by the second heat exchange assembly, in which each of the first heat exchange assemblies includes a pump that passes the refrigerant supplied from the first flow path through a cooling assembly that cools a respective one the objects to be cooled with the refrigerant, and sends the refrigerant to the second flow path.
(2)

The refrigerant circulation system according to (1), in which the first heat exchange assembly includes a housing that houses the pump, at least part of a forward path for the refrigerant, through which the refrigerant is sent from the first flow path to the cooling assembly, is located inside the housing, and a return path of the refrigerant, through which the refrigerant is sent from the cooling assembly to the second flow path, is located outside the housing.
(3)

The refrigerant circulation system according to (1) or (2), in which the heat exchanger is configured to be inserted into and removed from the second heat exchange assembly.
(4)

The refrigerant circulation system according to any one of (1) to (3), in which the second heat exchange assembly includes a plurality of the heat exchangers connected in parallel to the first flow path and the second flow path.
(5)

The refrigerant circulation system according to any one of (1) to (4), including a plurality of the second heat exchange assemblies.
(6)

The refrigerant circulation system according to any one of (1) to (5), including a filter connected in parallel between the first flow path and the pump, and a first valve located between the first flow path and the filter, and a second valve located between the filter and the pump.
(7)

The refrigerant circulation system according to any one of (1) to (6), in which the first heat exchange assembly includes a distribution flow path that distributes the refrigerant from the first flow path to a plurality of the pumps connected in parallel, and an expansion tank connected to the distribution flow path and configured to adjust an internal pressure.
(8)

The refrigerant circulation system according to any one of (1) to (7), in which each of the first heat exchange assemblies includes a temperature sensor to detect a temperature of the refrigerant sent from the cooling assembly to the second flow path, and a controller configured and/or programmed to adjust a flow rate of the pump in accordance with the temperature of the refrigerant detected by the temperature sensor.
(9)

The refrigerant circulation system according to (8), in which a temperature sensor to detect a temperature of the refrigerant sent from the pump to the cooling assembly is provided, and the controller is configured and/or programmed to adjust the flow rate of the pump in accordance with the temperature of the refrigerant before and after passing through the cooling assembly.
(10)

The refrigerant circulation system according to (8) or (9), including a controller connected to each of the first heat exchange assemblies and configured and/or programmed to adjust the flow rate of the pump of each of the first heat exchange assemblies, in accordance with the temperature of the refrigerant after passing through the cooling assembly of each of the first heat exchange assemblies.

Further effects and modified examples can be easily derived by those skilled in the art. Therefore, the broader aspects of the present disclosure are not limited to the specific details and representative example embodiments shown and described above. Accordingly, various modifications may be made without departing from the spirit or scope of the general inventive concept as defined by the appended claims and their equivalents.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A refrigerant circulation system comprising:
first heat exchange assemblies each provided for a respective one of objects to be cooled;
a second heat exchange assembly including a heat exchanger;
a first flow path to distribute a refrigerant from the second heat exchange assembly to the first heat exchange assemblies;
a second flow path to merge the refrigerant returned from the first heat exchange assemblies and allow the refrigerant to be collected by the second heat exchange assembly; wherein
each of the first heat exchange assemblies includes a pump that passes the refrigerant supplied from the first flow path through a cooling assembly that cools a respective one of the objects to be cooled with the refrigerant, and sends the refrigerant to the second flow path.

2. The refrigerant circulation system according to claim 1, wherein
the first heat exchange assembly includes a housing to house the pump;
at least a portion of a forward path of the refrigerant, through which the refrigerant is sent from the first flow path to the cooling assembly, is located inside the housing; and
a return path of the refrigerant, through which the refrigerant is sent from the cooling assembly to the second flow path, is located outside the housing.

3. The refrigerant circulation system according to claim 1, wherein
the heat exchanger is insertable into and removable from the second heat exchange assembly.

4. The refrigerant circulation system according to claim 1, wherein
the second heat exchange assembly includes a plurality of the heat exchangers connected in parallel to the first flow path and the second flow path.

5. The refrigerant circulation system according to claim 1, further comprising a plurality of the second heat exchange assemblies.

6. The refrigerant circulation system according to claim 1, further comprising:
a filter connected in parallel between the first flow path and the pump; and
a first valve located between the first flow path and the filter, and a second valve located between the filter and the pump.

7. The refrigerant circulation system according to claim 1, wherein
the first heat exchange assembly includes:
a distribution flow path to distribute the refrigerant from the first flow path to a plurality of the pumps connected in parallel; and
an expansion tank connected to the distribution flow path and configured to adjust an internal pressure.

8. The refrigerant circulation system according to claim 1, wherein
each of the first heat exchange assemblies includes:
a temperature sensor to detect a temperature of the refrigerant sent from the cooling assembly to the second flow path; and
a controller configured or programmed to adjust a flow rate of the pump in accordance with the temperature of the refrigerant detected by the temperature sensor.

9. The refrigerant circulation system according to claim 8, wherein
a temperature sensor to detect a temperature of the refrigerant sent from the pump to the cooling assembly is provided; and
the controller is configured or programmed to adjust the flow rate of the pump in accordance with the temperature of the refrigerant before and after passing through the cooling assembly.

10. The refrigerant circulation system according to claim 8, further comprising:
a controller connected to each of the first heat exchange assemblies and configured or programmed to adjust the flow rate of the pump of each of the first heat exchange assemblies, in accordance with the temperature of the refrigerant after passing through the cooling assembly of each of the first heat exchange assemblies.
